(19) United States
(12) Patent Application Publication
(10) Pub. No.: US 2011/0043037 A1
(43) Pub. Date: Feb. 24, 2011

(54) NANOSTRUCTURED HIGH SURFACE AREA ELECTRODES FOR ENERGY STORAGE DEVICES

(76) Inventors: David N. Mcilroy, Moscow, ID (US); Grant Norton, Pullman, WA (US)

Correspondence Address: K&L Gates LLP;IP Docketing, 630 HANSEN WAY, PALO ALTO, CA, 94304, US

(21) Appl. No.: 12/864,217

(22) PCT Filed: Jan. 22, 2009
(86) PCT No.: PCT/US09/31728

§ 371 Date: Oct. 18, 2010

(30) Foreign Application Priority Data
Jan. 22, 2008 (US) 61022799

(51) Int. Cl. H02J 3/28; H01G 9/058; H01G 9/04; H01G 9/035; H02J 9/00; H02M 3/06; C25B 11/00; C25B 11/04; C25B 11/08; B05D 5/12; H01L 21/36; B82Y 30/00; B82Y 40/00

(52) U.S. Cl. 307/48; 361/502; 361/523; 361/503; 307/66; 307/109; 204/290.01; 204/290.15; 204/290.14; 427/58; 438/478; 977/948; 977/773; 257/E21.461

(57) ABSTRACT

High surface area electrodes are described here. The electrodes comprise a conductive substrate and a mesh of nanostructures disposed on the conductive substrate. The nanostructures are coated with conductive or semiconducting nanoparticles to form a high surface area electrode. Methods for making high surface area electrodes are also provided. Further, energy storage devices incorporating the high surface area electrodes are described. Related systems incorporating energy storage devices are also disclosed.

### CROSS REFERENCE TO RELATED APPLICATIONS

This application claims priority benefit of United States Provisional Application No. 61/022,799, entitled “Nanostructured High Surface Area Electrodes for Energy Storage Devices” filed Jan. 22, 2008, the content of which is hereby incorporated by reference in its entirety as if it was put forth in full below.

### FIELD

This application relates to high surface area electrodes, to energy storage devices incorporating such high surface area electrodes, and to related systems and methods.

### BACKGROUND

In a capacitor, energy may be stored as an electric field generated between two oppositely charged electrodes. The energy stored by a capacitor is QV/2, where Q is the stored charge and V is the voltage between the two electrodes. The amount of charge that can be stored is proportional to the surface area of the electrodes. In general, it is possible to generate larger electric fields, and hence store more energy, between high surface area electrodes that are separated by small distances.

In double layer capacitors, or ultracapacitors, a volume between two opposite polarity electrodes is filled with an electrolyte, and a dielectric separator permeable to ions of the electrolyte is positioned in the electrolyte to effectively partition the volume between the two electrodes. Charge can then build up at each of the opposite polarity electrodes to store energy. Ultracapacitors may be capable of high storage capacities because of the small distance between the electrodes. In some cases, metal electrodes may be coated with activated carbon to effectively increase the surface area of the electrodes and hence the energy storage capacity of an ultracapacitor. Ultracapacitors may be capable of storing more power per unit weight (power density) than conventional batteries, and may be capable of storing more energy per unit weight (energy density) than conventional (e.g., electrolytic or dielectric) capacitors.

Thus, there exists a need for improved high surface area electrodes for use in energy storage devices, for example high surface area electrodes that may be used in ultracapacitors. There also exists a need for improved energy storage devices, e.g., energy storage devices that have increased power density, increased energy density, and faster charging times.

### SUMMARY

Described here are high surface area electrodes that comprise metallized nanostructures. These electrodes may be used in any device utilizing high surface area electrodes, and in particular, they may be used in energy storage devices such as ultracapacitors. Also described here are energy storage devices incorporating high surface area electrodes comprising metallized nanostructures. It is anticipated that the energy storage devices described here may exhibit energy density storage capabilities of at least about 2 to at least about 5 times that of a conventional ultracapacitor made with activated carbon-coated metal electrodes.

In general, the high surface area electrodes described here comprise a conductive substrate and a mesh of nanostructures disposed on the conductive substrate. In some variations, the mesh of nanostructures may be grown directly on the substrate. The nanostructures making up the mesh are coated with conductive or semiconducting nanoparticles. The conductive or semiconducting nanoparticles may be present at a coverage sufficient to provide an effective conductive surface on the electrode of at least about 1,000 cm², at least about 2,000 cm², at least about 3,000 cm², at least about 5,000 cm², at least about 8,000 cm², at least about 10,000 cm², at least about 12,000 cm², at least about 15,000 cm², at least about 18,000 cm², or at least about 20,000 cm² per square cm of the substrate.

The conductive substrate may be any suitable substrate, and may comprise one material or more than one material, e.g., more than one conducting material, or a conducting material and an insulating material. For example, the conductive substrate may comprise a metal, a metal alloy, a semiconductor, a conductive polymeric material such as a conductive polymer or a conductive polymeric composite, or any combination thereof. In some cases, the conductive substrate may comprise multiple layers, e.g., a multilayer structure such as a metal layer deposited on a ceramic, glass, or polymeric or polymer composite substrate. If the nanostructures are grown directly on the conductive substrate, the substrate may be selected to be able to withstand the processing temperatures required to grow the nanostructures. In some variations, the substrate may be aluminum.

At least some of the nanostructures forming the mesh may be helical (i.e., nanosprings). In some cases, at least some of the nanostructures may be nanowires or nanotubes. The nanostructures may be single strand or multistrand. In a single mesh, a combination of nanostructures may be present, e.g., a combination of nanosprings and nanowires, and/or single strand and multistrand nanostructures. The nanostructures may be formed of any suitable material, e.g., SiO₂, SiC, or GaN. In general, the mesh formed of the nanostructures may have a depth of about 1 micron to about 100 microns. An areal density of nanostructures on the substrate may be about 5×10⁷/cm² to about 1×10¹¹/cm².

The conductive or semiconducting nanoparticles attached to the nanostructures may comprise any suitable conductive material, e.g., metals, metal alloys, metal oxides, carbon, and any combination thereof. In some variations, the nanoparticles may comprise gold, nickel, copper, aluminum, silver, platinum, palladium, zinc oxide, indium tin oxide, or combinations thereof. The nanoparticles may have a dimension, e.g., a diameter, of about 100 nm or smaller, e.g., about 50 nm or smaller.

The electrodes described here may be used in any application requiring a high conductive surface area electrode. In particular, the electrodes may be useful in energy storage devices such as capacitors, e.g., ultracapacitors.

Methods for making high surface area electrodes are also provided here. In general, the methods comprise providing a conductive substrate that comprises a mesh of nanostructures secured thereto, and coating the nanostructures with conductive or semiconducting nanoparticles at a coverage sufficient to provide a high surface area conductive electrode surface. In some variations, the methods may result in an electrode having a conductive surface area of at least about 5,000 cm², or at least about 10,000 cm², or at least about 20,000 cm² in a 1 cm² boundary.

In some variations of the methods, the mesh of nanostructures may be grown directly on the conductive substrate. In these variations, the nanostructures may be grown at a temperature of about 300° C. to about 1100° C. For example, the methods may comprise growing a mesh of nanostructures by applying a thin film catalyst to the conductive substrate, and heating the substrate in a chamber to maintain a vapor pressure of one or more nanostructure precursor materials, and in some cases, to liquefy the thin film catalyst. The methods may include varying a depth of the mesh of nanostructures by varying the thickness of the thin film catalytic layer.

The conductive substrate used in the methods may be selected based on the temperature required to liquefy the thin film catalyst and/or to maintain a vapor pressure of the nanostructure material(s). The methods may comprise using a conductive substrate that comprises a metal, a metal alloy, a semiconductor, a ceramic, a glass, a polymeric material such as a polymeric composite, a conductive polymeric material or a conductive polymeric composite, or any combination thereof. In some variations, multilayer conductive substrates may be used in the methods, e.g., a conductive substrate may comprise a conductive layer on an insulating layer, such as a metal layer on a glass, ceramic, or polymeric layer. In some variations of the methods, aluminum may be used as the conductive substrate.

Any suitable type of nanostructures may make up the mesh. For example, the nanostructures may comprise nanosprings, nanowires, nanotubes, multistrand nanostructures, single strand nanostructures, or any combination thereof. The nanostructures may be made of any suitable material. For example, nanostructures may comprise SiO₂, SiC, or GaN.

The coating of the nanostructures with conductive or semiconducting nanoparticles may be accomplished using any suitable method. For example, conductive or semiconducting nanoparticles may be deposited using atomic layer deposition, chemical vapor deposition, or plasma enhanced chemical vapor deposition. In general, the methods include depositing the conductive or semiconducting nanoparticles at a coverage sufficient to result in a high conductive surface area electrode. This may be accomplished by depositing uniformly dimensioned and/or small dimension conductive or semiconducting nanoparticles. For example, in some variations, the methods comprise depositing conductive or semiconducting nanoparticles having a dimension, e.g., a diameter, of about 100 nm or less, or about 50 nm or less.

In the methods described here, the conductive or semiconducting nanoparticles may be selected from the group consisting of metals, metal alloys, metal oxides, carbon, and combinations thereof. For example, in certain variations, the conductive or semiconducting nanoparticles may comprise gold, nickel, copper, aluminum, silver, platinum, palladium, zinc oxide, indium tin oxide, or combinations thereof.

Energy storage devices are also described here. The energy storage devices comprise first and second electrodes. At least one of the electrodes comprises a conductive substrate and a mesh of nanostructures coated with conductive or semiconducting nanoparticles, the mesh being disposed on at least a portion of the substrate. An electrolyte is disposed in a volume between the first and second electrodes. An insulating (separator) layer that is permeable to ions of the electrolyte is disposed in the volume between the first and second electrodes to partition the volume.

In some variations of the energy storage devices, the first electrode may comprise a first mesh of nanostructures coated with conductive or semiconducting nanoparticles the first mesh disposed on at least a portion of a first conductive substrate, and the second electrode may comprise a second mesh of nanostructures coated with conductive or semiconducting nanoparticles, the second mesh disposed on at least a portion of a second conductive substrate. At least one of the first and second meshes may have a depth of about 1 micron to about 100 microns. In these variations, the first and second meshes may be the same or different, and the nanoparticles used to coat the nanostructures on the first and second meshes may be the same or different.

In the energy storage devices, the nanostructures making up the mesh may have any suitable structure, e.g., nanosprings, nanowires, nanotubes, single strand nanostructures, multistrand nanostructures, or any combination thereof. The nanostructures may be formed from any suitable material. For example, nanostructures on at least one of the first and second electrodes may comprise SiO₂, GaN, or SiC. An areal density of the nanostructures on the substrate may be about 5×10⁷/cm² to about 1×10¹¹/cm².

For the energy storage devices, the conductive or semiconducting nanoparticles used to metallize the mesh of nanostructures may comprise a metal, a metal alloy, a metal oxide, carbon, or combinations thereof. In some variations of the devices, the conductive or semiconducting nanoparticles may comprise gold, nickel, copper, aluminum, silver, platinum, palladium, zinc oxide, indium tin oxide, or combinations thereof. The conductive or semiconducting nanoparticles may be coated on the nanostructures forming the mesh to result in an electrode having an effective conductive surface area of at least about 1,000 cm², at least about 2,000 cm², at least about 3,000 cm², at least about 5,000 cm², at least about 8,000 cm², at least about 10,000 cm², at least about 12,000 cm², at least about 15,000 cm², at least about 18,000 cm², or at least about 20,000 cm², or even higher, e.g., at least about 22,000 cm², per square cm of the substrate. In some variations of devices, the nanoparticles may have a dimension of about 100 nm or less, e.g., about 50 nm or less. The energy storage devices may be used in any suitable application, e.g., in a vehicle or an automobile, such as a hybrid electric vehicle, or in an electronic system, or in a computer system.

Systems are also provided here. In general, the systems comprise an energy source and an ultracapacitor. The ultracapacitor in the systems comprises first and second electrodes. At least one of the electrodes in the ultracapacitor comprises a conductive substrate and a mesh of nanostructures coated with conductive or semiconducting nanoparticles, the mesh being disposed on at least a portion of the conductive substrate. In the ultracapacitor, an electrolyte is disposed in a volume between the first and second electrodes. An insulating (separator) layer that is permeable to ions of the electrolyte is disposed in the volume between the first and second electrodes to partition the volume. In the systems, the ultracapacitor may be configured to provide back-up energy for the energy source, augment the energy delivered by the energy source, and/or store energy regenerated by the system. The energy source in some variations of the system may comprise a battery. In other variations, the energy source may comprise a fuel cell. The systems may be configured for use in an automobile or vehicle.

### BRIEF DESCRIPTION OF THE FIGURES

FIG. 1 shows a scanning electron microscope image of an example of a mesh of nanostructures that may be used in the high surface area electrodes and energy storage devices described here.

FIG. 2 shows a transmission electron microscope image of an example of an individual silica nanostructure.

FIG. 3 shows a scanning electron microscope image of silica nanostructures that have been metallized with gold nanoparticles.

FIG. 4 shows a scanning electron microscope image of silica nanostructures that have been coated with zinc oxide nanoparticles.

FIG. 5 provides an exemplary X-ray diffraction spectrum of zinc oxide nanoparticles that have been deposited on silica nanostructures.

FIG. 6 illustrates an example of an energy storage device incorporating electrodes comprising metallized nano structures.

FIG. 7 illustrates another example of an energy storage device incorporating electrodes comprising metallized nanostructures.

### DETAILED DESCRIPTION

Described here are high surface area electrodes, methods for making high surface area electrodes, energy storage devices incorporating such high surface area electrodes, and related systems. In general, the electrodes comprise a conductive substrate comprising conductive nanostructures that form a conductive surface having a high surface area. The conductive nanostructures may be formed by adhering conductive or semiconducting nanoparticles to nanostructures grown directly on the conductive substrate. The mesh formed by the conductive nanostructures comprise features or crevices of such a scale that the effective surface area is increased and is still accessible to make effective electrical contact, e.g., by ions in an electrolyte. A “feature” or “crevice” of the mesh is meant to encompass any topological feature of the mesh, e.g., intra-nanostructure spaces such as spaces inside tubular or hollow regions, or between coils of a helical structure, and inter-nanostructure spaces.

I. High surface area electrodes and methods of making high surface area electrodes

### A. Nanostructures

The electrodes described here comprise a mesh of nanostructures, where the nanostructures may comprise a variety of structures such as nanosprings, nanowires, nanorods, nanotubes, single strand nanostructures, multistrand nanostructures, and any combination thereof. The mesh formed by the nanostructures is disposed on at least a portion of a conductive substrate. As used herein, “nanostructure” is meant to encompass any structure having at least one dimension of 100 nm or smaller, and “nanoparticle” is meant to encompass any particle having at least one dimension of 100 nm or smaller. As used herein, “mesh of nanostructures” is meant to encompass any kind of three-dimensional mat or network of nanostructures, where the nanostructures exhibit some degree of intertwining or entanglement. The conductive substrate may be any suitable substrate, may be single layer or multilayer, may comprise one or more conductive materials, e.g., a metal, a metal alloy, a conductive polymer, a conductive polymeric composite, or may comprise an insulator and a conductive material, e.g., a metal-coated ceramic or glass, and/or a metal-coated polymeric material.

In general, the mesh of nanostructures may be grown directly on the conductive substrate, so that a binder is not required to adhere the nanostructures to the substrate. For example, a mesh of nanostructures such as described in International Patent Application No. PCT/US2006/024435, “Method for Manufacture and Coating of Nanostructured Components,” filed Jun. 23, 2006, and incorporated herein by reference in its entirety, may be used for the electrodes.

The nanostructures used in the electrodes may comprise a glass (e.g., silica (SiO₂ or SiOₓ)), a ceramic (e.g., SiC, BN, B₄C or Si₃N₄), a ceramic oxide (e.g., Al₂O₃ or ZrO₂), a metal or semiconductor (e.g., Si, Al, C, Ge, GaN, GaAs, InP or InN). In some variations, a mesh of nanostructures on the conductive substrate may be formed by pre-treating the substrate by depositing a thin film catalyst on the substrate, heating the pre-treated substrate together with gaseous, liquid, and/or solid nanostructure precursor material or materials, and then cooling slowly under a relatively constant flow of an inert gas to room temperature. If more than one precursor material is used, the precursor materials may be added in a serial or parallel manner.

The concentration of precursor material(s) and/or heating time of the pretreated substrate together with the precursor material(s) may be varied to adjust properties of the resultant mesh of nanostructures (e.g., mesh thickness and/or nanostructure density). Typical heating times are from about 15 minutes to about 60 minutes. Molecular or elemental precursors that exist as gases or low boiling liquids or solids may be used so that processing temperatures as low as about 350° C. may be used. The processing temperature may be sufficiently high for the thin film catalyst to melt, and for the molecular or elemental precursor to decompose into the desired components. These nanostructure-growing processes may allow the use of a wide variety of substrates. For example, conductive substrates comprising metal, glass, a semiconductor, or a ceramic may be used, e.g., metal-coated ceramic substrates. In some variations, relatively low-melting point substrates may be used, such as aluminum, or polymeric materials that are inherently conductive (conductive polymers) or have been made conductive with conductive fillers and/or coatings (e.g., polyimides or other polymers or polymer composites having a sufficiently high T_{g} to allow relatively short excursions to about 350° C.).

The thin film catalyst may be applied to the substrate using any suitable method. For example, thin films of metal or metal alloy catalysts may be applied using plating, chemical vapor deposition, plasma enhanced chemical vapor deposition, thermal evaporation, molecular beam epitaxy, electron beam evaporation, pulsed laser deposition, sputtering, and combinations thereof. In general, the thin catalyst film is applied as a relatively uniform distribution (e.g., a contiguous or nearly contiguous uniform layer) to allow for relatively uniform growth of nanostructures. The thickness of the thin film catalyst may be varied to tune properties of the resultant mesh of nanostructures (e.g., a thickness of the mesh and/or a density of the nanostructures). In some variations, the thickness of the thin film catalyst may be from about 5 nm to about 200 nm. Non-limiting examples of materials that may be used as the thin film catalyst include Au, Ag, Fe, FeB, NiB, Fe₃B and Ni₃B. In some variations, the thin film catalyst layer may be formed as a patterned layer on the substrate (e.g., through the use of masking and/or lithography) to result in a correspondingly patterned mesh of nanostructures. If a mask is used to pattern the catalytic thin film, the mask may be removed before or after growth of the nanostructures from the catalytic thin film. After a thin film catalyst layer has been applied to the substrate, the substrate is heated, in some cases so that the catalyst layer melts to form a liquid, and one or more nanostructure precursor materials are introduced in gaseous form so that they can diffuse into the molten catalytic material to begin catalytic growth of the nanostructures.

In some variations of these processes, a pre-treated substrate may be heated together in a chamber at a relatively constant temperature to generate and maintain a vapor pressure of a nanostructure precursor element. In these variations, non-limiting examples of nanostructure precursor materials include SiH₄, SiH(CH₃)₃, SiCl₄, Si(CH₃)₄, GeH₄, GeCl₄, SbH₃, AlR₃, where R may for example be a hydrocarbon, Hg, Rb, Cs, B, Al, Zr and In.

In other variations of these processes, a pre-treated substrate may be heated in a chamber together with a solid elemental nanostructure precursor at a relatively constant temperature that is sufficient to generate and maintain a vapor pressure of the nanostructure precursor element. In these variations, non-limiting examples of the solid elemental nanostructure precursor include C, Si, Ga, B, Al, Zr and In. In some of these variations, a second nanostructure precursor may be added into heated chamber, e.g., by introducing a flow or filling the chamber to a static pressure. Non-limiting examples of the second nanostructure precursor include CO₂, CO, NO and NO₂.

In still other variations, a pre-treated substrate may be heated in a chamber to a set temperature at least about 100° C., and a first nanostructure precursor material may be introduced into the chamber through a gas flow while the chamber is heated to the set temperature. After the chamber has reached the set temperature, the temperature may be held relatively constant at the set temperature, and a second nanostructure precursor material may be flowed into the chamber. In these variations, non-limiting examples of the first and/or second nanostructure precursor materials include SiH₄, SiH(CH₃)₃, SiCl₄, Si(CH₃)₄, GeH₄, GeCl₄, SbH₃, AlR₃ (where R is for example a hydrocarbon group), CO₂, CO, NO, NO₂, N₂, O₂, and Cl₂.

For example, to make a mesh comprising helical silica nanostructures, a substrate capable of withstanding at least about 350° C. for about 15 to 60 minutes may be pre-treated by sputtering a thin, uniform layer of Au on the substrate (e.g., a layer about 15 nm to about 90 nm thick). To achieve the desired Au thickness, the substrate may be placed into a sputtering chamber at about 60 mTorr, and an Au deposition rate of about 10 nm/min may be used while maintaining a constant O₂ rate during deposition. The substrate that has been pre-treated with Au may be placed in a flow furnace, e.g., a standard tubular flow furnace that is operated at atmospheric pressure. A set temperature in the range of about 350° C. to about 1050° C., or even higher, may be selected depending on the substrate used. During an initial warm up period in which the furnace is heated to the set temperature, a 1 to 100 standard liters per minute (slm) flow of SiH(CH₃)₃ gas is introduced into the furnace for about 10 seconds to about 180 seconds, and then turned off. After the flow of SiH(CH₃)₃ is terminated, pure O₂ may be flowed through the furnace at a rate of about 1 to 100 slm. The furnace is then held at the set temperature for about 15 to about 60 minutes, depending on the desired properties of the mesh of silica (SiO₂ or SiOₓ) nanostructures.

A range of densities of nanostructures on the substrate may be made with the methods described here. The density of nanostructures on the substrate may be varied by varying the thickness of the thin film catalyst deposited on the substrate. If the thin film catalyst layer is relatively thick (e.g., 30 nm or thicker), the nanostructures may be very densely packed with nanostructures comprising groups of intertwined and/or entangled nanostructures, e.g., nano springs, or a combination of nanostructures. A relatively thin catalyst film (e.g., about 10 nm or thinner) may result in nanostructures that may be widely spaced apart, e.g., about 1 μm apart or even farther). For example, an areal density of nanostructures on the substrate of about 5×10⁷ nanostructures per square cm to about 1×10¹¹ nanostructures per square cm may be achieved.

The areal density of nanostructures on a substrate may be estimated using the initial thickness of the thin film catalyst layer, and the average size of the catalyst particle or droplet left at the end of each nanostructure formed. The initial thickness of the thin film catalyst layer may be determined using an atomic force microscope, by examining a border between a catalyst-coated area (e.g., a gold-coated area) and an uncoated area of the substrate. The average catalyst size may be determined from the wavelength of the catalyst plasmon (e.g., the Au plasmon) obtained from a mesh or mat formed from nanostructures, e.g., nanosprings. In some variations, multiple layers of nanostructures (e.g., nanosprings) can be formed by depositing a catalyst layer onto an existing mat or mesh, whereby nanostructures are grown on top of the existing mat or mesh by the previously described process. This catalyst may, for example, be nanoparticles (e.g., gold nanoparticles) that have been coated onto the nanostructures in the existing mat or mesh. In some variations, each layer in a mesh or mat may have a depth of about 10 μm, and multiple layers may be built up to provide a mesh or mat that has a depth of about 20 μm, about 30 μm, about 50 μm, about 80 μm, about 100 μm, or even thicker, e.g., about 200 μm.

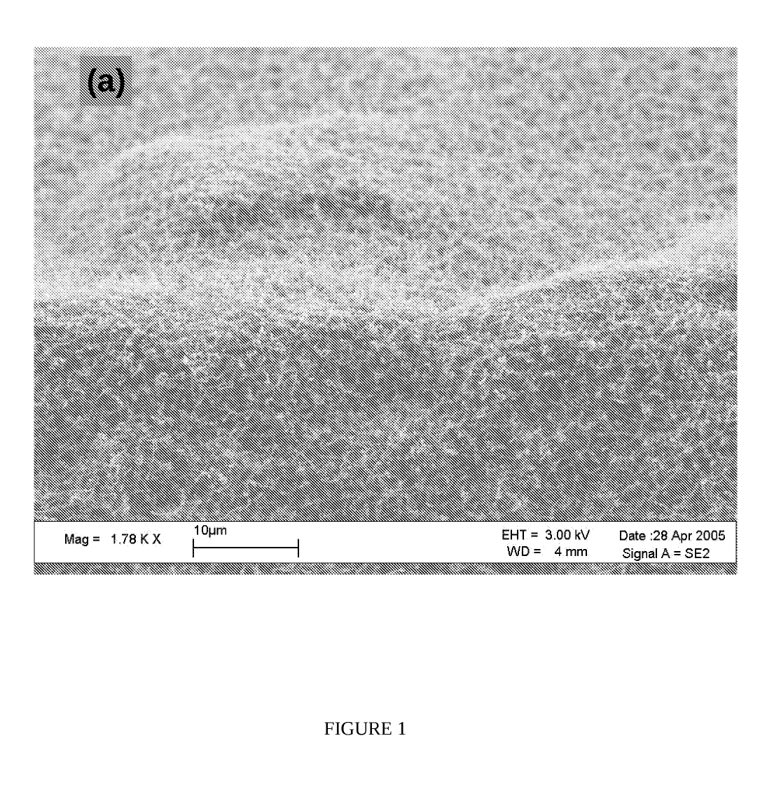

An example of a mesh of silica nanostructures is shown in FIG. 1. There, a scanning electron microscope (SEM) image shows a mat or mesh of silica nanostructures that has been grown on a silicon substrate. In this particular example, a 60 nm thin film gold catalyst was sputtered onto the silicon substrate. The silica nanostructures were grown with SiH(CH₃)₃ at a temperature of 400° C. for 30 minutes. The SEM image has been acquired with a AMRAY 1830 field emission SEM at 15 kV. The scale bar shown indicates a dimension of 10 μm. As shown in FIG. 1, the nanostructures form a complex three-dimensional mesh or mat, with many nanostructures intertwined and/or entangled with other nanostructures. Nanostructures may have a length of about 1 nm to about 10 μm, or longer, e.g., tens of microns. The mesh or mat itself may have a depth (i.e., a distance from the surface of the substrate to which the nanostructures are attached to a top surface of the mesh) of about 1 μm to about 100 μm. In some variations, relatively thick (e.g., greater than about 30 μm, or about 50 μm, or about 80 μm) meshes may be formed with multiple layers of nanostructures as described above.

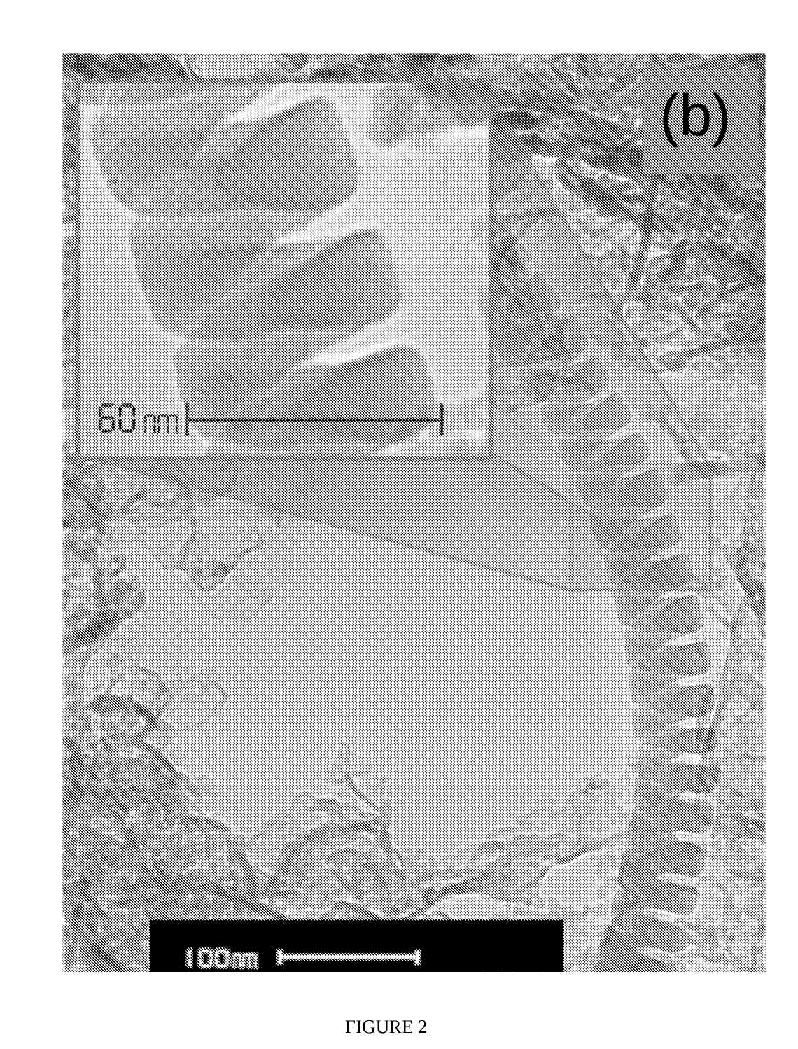

Referring now to FIG. 2, a transmission electron microscope (TEM) image of an individual nanostructure is shown. The TEM image was obtained using a Philips CM200 TEM operating at 200 kV. The scale bar indicates a dimension of 100 nm. This nanostructure was grown under similar conditions as those shown in FIG. 1. As shown in the inset of FIG. 2, in this particular case, the nanostructure has a helical shape, and a cross-sectional diameter of about 60 nm. As stated above, other types and dimensions of nanostructures may be used or grown to make the high surface area electrodes, e.g., multistrand nanostructures may be used or grown.

### B. Metallization of Nanostructures

As described above, the nanostructures that make up the three-dimensional mesh or mat that is disposed on at least a portion of the conductive substrate may be metallized. “Metallize” as used herein refers to any process by which conductive or semiconducting nanoparticles are applied to, attached to, or formed on the nanostructures, e.g., by depositing and/or growing conductive or semiconducting nanoparticles on the nanostructures. The nanostructures may be metallized or coated with conductive or semiconducting nanoparticles with a coverage that is sufficient to form a high surface area conductive electrode. To take advantage of the high surface area provided by the mesh of nanostructures, the conductive or semiconducting nanoparticles may coat the nanostructures uniformly to provide a contiguous conductive surface, e.g., over a majority of the surface area of the nanostructures forming the mesh. Further, the conductive or semiconducting nanoparticles may have small enough dimensions and/or narrow enough particle size distributions that they may coat individual nanostructures in a relatively conformal manner, e.g., without filling or blocking substantial intra-nanostructure spaces or inter-nanostructure spaces. For example, the conductive or semiconducting nanoparticles may form a conformal coating of about 30 nm, about 50 nm, about 60 nm, about 70 nm, about 80 nm, about 90 nm, or about 100 nm thick. Thus, the nanoparticle coating may result in a dimension of a coated nanostructure increasing by a factor of about 2, about 3, about 4, or in some case, an even high factor, as compared to an uncoated nanostructure. By coating the nanostructures with a contiguous or nearly contiguous coating of conductive or conducting nanoparticles as described, conductive pathways over a majority of the surface area of the mesh of nanostructures may be formed, e.g., there may be a conductive path between one surface region of the mesh located near an edge of the mesh and another surface region of the mesh near an opposed edge of the mesh.

The conductive or semiconducting nanoparticles may comprise any suitable material, e.g., metals, metal alloys, metal oxides, carbon, or any combination thereof. For example, carbon nanoparticles may be used. In some variations, gold nanoparticles may be used. In other variations, zinc oxide nanoparticles may be used. In still other variations, indium tin oxide nanoparticles may be used. In still other variations, nickel, copper, aluminum, silver, platinum, palladium or combinations thereof may be used. In some variations, the metallization or coating of the nanostructures with nanoparticles may comprise more than one layer. For example, more than one metal layer may be used, e.g., a very thin gold, nickel or platinum layer may be applied on top of another metal layer. In some variations, an interfacial layer may be applied on the nanostructures to promote the formation or adhesion of the conductive or semiconducting nanoparticles.

The conductive or semiconducting nanoparticles may be applied to the nanostructures using any suitable method. For example, the conductive or semiconducting nanoparticles may be applied using atomic layer deposition (ALD), chemical vapor deposition (CVD), or plasma-enhanced chemical vapor deposition (PECVD). In general, the nanoparticles may have an average diameter of about 100 nm or less, about 50 nm or less, about 40 nm or less, about 30 nm or less, about 20 nm or less, or about 10 nm or less, or even smaller, about 5 nm or less, e.g., about 4 nm, about 3 nm, or about 2 nm. Further, the standard deviation of the distribution of nanoparticle diameters applied to the nanostructures may be less than about 100%, less than about 80%, less than about 50%, less than about 30%, less than about 20%, or less than about 10%. In some cases, more than one average size nanoparticle may be applied to the meshes, e.g., in multiple applications. For example, a first application may apply relatively large particle sizes, e.g., about 5 to about 50 nm, and the second application may apply relatively small particles sizes, e.g., less than about 10 nm. A combination of nanoparticle sizes may allow for greater packing of the nanoparticles, e.g., where smaller nanoparticles may fill in voids or gaps in the coverage by the relatively large nanoparticles. Nanoparticle dimensions and/or nanoparticle particle distributions may be selected so that a relatively conformal and contiguous metallized coating of the complex surface of the nanostructures may be achieved, to yield a very high surface area conductive electrode surface. For example, an area on the substrate defined by a 1 cm square boundary may have an effective conductive surface area of at least about 1,000 cm², at least about 2,000 cm², at least about 3,000 cm², at least about 5,000 cm², at least about 8,000 cm², at least about 10,000 cm², at least about 12,000 cm², at least about 15,000 cm², at least about 18,000 cm², at least about 20,000 cm², or even higher, e.g., at least about 22,000 cm². Thus, the conductance of a square centimeter of a mesh metallized with conductive or semiconducting nanoparticles may be a factor of at least about 1,000, at least about 2,000, at least about 3,000, at least about 5,000, at least about 8,000, at least about 10,000, at least about 12,000, at least about 15,000, at least about 18,000, at least about 20,000, or even higher, e.g., at least about 22,000, times greater than the conductance of a square centimeter planar surface similarly metallized with the same conductive or semiconducting nanoparticles.

To achieve a desired degree of contiguous and conformal metallized coating of the nanostructures, the conductive or semiconducting nanoparticles may be deposited or grown on the nanostructures in such a manner to control average conductive or semiconducting nanoparticle size and distribution. In some variations, the nanostructures may be metallized in a parallel plate PECVD chamber operated about 13.56 MHz. The chamber volume is about 1 cubic meter. The parallel plates are 3″ in diameter and separated by 1.5″. A nanoparticle precursor and carrier gas (e.g., argon) mixture may be introduced into the chamber from a nozzle in the center of the anode, and the sample holder may serve as a ground plate. The temperature and the pressure of the deposition process may be varied to vary the average nanoparticle size and particle size distribution. PECVD may be used to grow a variety of conductive or semiconducting nanoparticles, with non-limiting examples including gold, nickel, platinum, copper, aluminum, silver, palladium, zinc oxide, indium tin oxide, or combinations thereof. For example, dimethyl(acetylacetonate)gold(III) may be used as a precursor for gold nanoparticles, bis(cyclopentadienyl)nickel may be used as a precursor for nickel nanoparticles, and (trimethyl)methylcyclopentadienylplatinum(IV) may be used as a precursor for platinum nanoparticles. Each of these precursors is commercially available from Strem Chemicals, Newburyport, Mass.

Gold nanoparticles having small average particles sizes and narrow particle size distributions may be produced on silica nanostructures using PECVD at pressures between about 17 Pa and 67 Pa, and at substrate temperatures of about 573K to about 873K. For example, gold nanoparticles having an average particle diameter of about 5 nm, with a standard deviation of 1 nm may be deposited on silica nanostructures using PECVD with a total chamber pressure of about 17 Pa, a substrate temperature of 573K, a precursor material of dimethyl(acetylacetonate)gold(III), and argon as a carrier gas. Gold nanoparticles having an average diameter of 7 nm with a standard deviation of 2 nm may be similarly produced, except with a total chamber pressure of 72 Pa and a substrate temperature of 723K. Gold nanoparticles having an average diameter of 9 nm with a standard deviation of 3 nm may be produced with a total chamber pressure of 17 Pa and a substrate temperature of 873K. Additional examples of gold nanoparticle distributions that may be formed on silica nanostructures are described in A. LaLonde et al., “Controlled Growth of Gold Nanoparticles on Silica Nanowires,” Journal of Materials Research, 20 (2005) 3021-3027, which is hereby incorporated by reference in its entirety.

Other conductive or semiconducting nanoparticles may be deposited onto nanostructures using PECVD or CVD using starting materials and deposition conditions known in the art. For example, carbon nanoparticles having average diameters of about 50 nm or less may be deposited on silica nanostructures using carbon containing precursors, e.g. C₂H₂, etc., by PECVD or CVD.

### Example 1

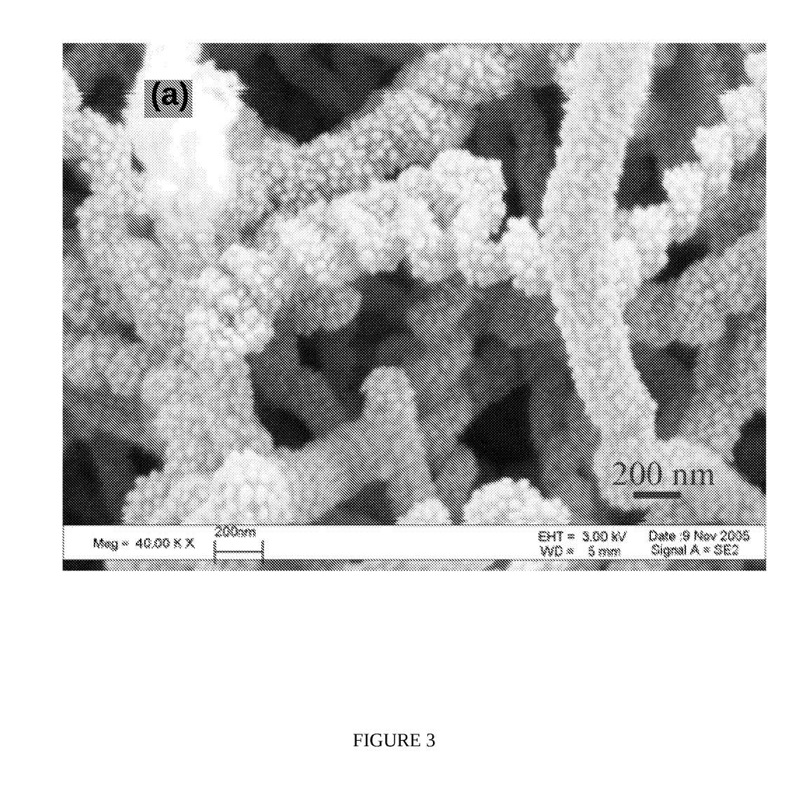

FIG. 3 shows an SEM image of Example 1, which illustrates a mesh of metallized nanostructures that may be used to form a high surface area electrode. In this Example, the nanostructures have been metallized with a uniform, contiguous coating of small gold nanoparticles that follow the contours of nanostructures to form a very high surface area conductive surface that may be used in an electrode.

In Example 1, a three-dimensional mesh comprising intertwined helical silica nanostructures has been formed on a silicon substrate. A 60 nm layer of gold was sputtered onto the substrate as a thin catalytic layer. The silica nanostructures were grown in a tube furnace at atmospheric pressure, with the substrate temperature at about 350° C. for about 30 minutes. The areal density of nanostructures per square centimeter was calculated to be about 2.25×10¹⁰ by using the average size (80 nm) of the gold catalyst particles on the ends of the grown nanostructures.

After the nanostructures were formed, they were metallized with gold nanoparticles using PECVD as described above. In Example 1, the precursor material used was dimethyl(acetylacetonate)gold(III), available from Strem Chemicals. The carrier gas was argon, with total chamber pressures ranging from 10 to 70 Pa, substrate temperatures ranging from 573 K to 873 K, and deposition times ranging from 8 to 15 minutes, e.g., 12 minutes. Because the gold nanoparticles form a contiguous uniform coating that follows the contours of the nanostructures without filling in or blocking surface area, a very high conductive surface area electrode may be formed by metallizing silica nanostructures with gold as in Example 1, and using a conductive substrate (e.g., aluminum) instead of a silicon substrate on which to grow the silica nanostructures.

As stated above, other methods may be used to apply conductive or semiconducting nanoparticles to nanostructures to make high surface area conductive electrodes. In some variations, nanoparticles of metal oxides may be applied to nanostructures using atomic layer deposition (ALD). In these variations, the nanoparticle size and distribution may be controlled by varying the nanoparticular precursor material pressure, purge time, and number of deposition cycles. For example, to metallize nanostructures with a contiguous uniform coating of zinc oxide nanoparticles or indium tin oxide nanoparticles having an average dimension of about 100 nm or smaller, or about 50 nm or smaller. Any suitable atomic layer deposition conditions known in the art may be used. For example, zinc oxide nanoparticles may be deposited using the procedures disclosed in E. B. Yousfi et al., “Atomic layer deposition of zinc oxide and indium sulfide layers for Cu(In,Ga)Se₂ thin-film solar cells,” Thin Solid Films, 387, 29-32 (2001), which is hereby incorporated by reference in its entirety.

### Example 2

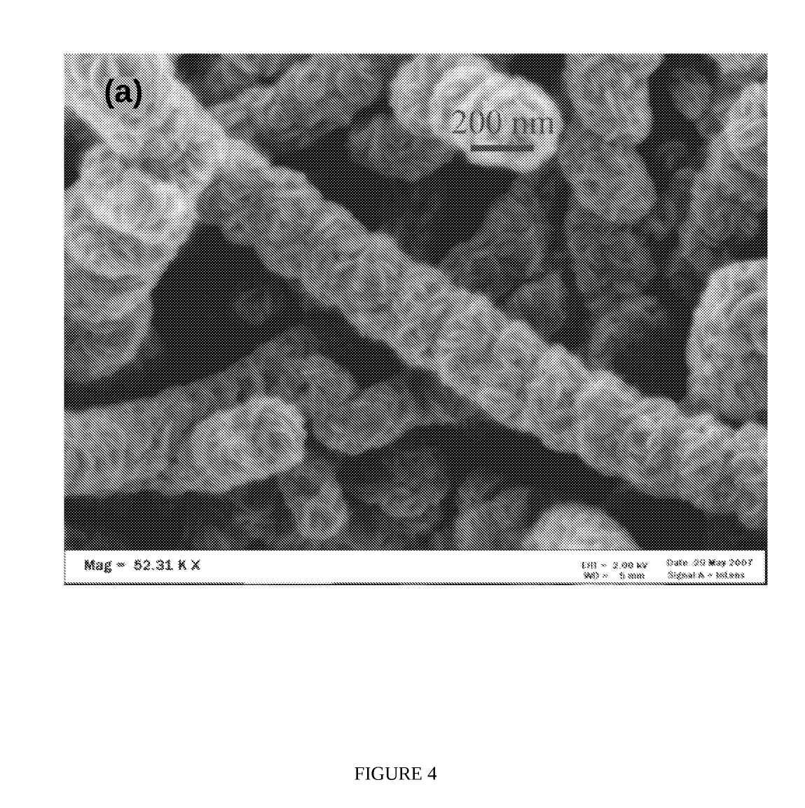

FIG. 4 shows an SEM image of Example 2, which illustrates another mesh of metallized nanostructures that may be used to form a high surface area electrode. In this Example, the nanostructures are metallized with conductive zinc oxide nanoparticles. In Example 2, a mesh of helical silica nanostructures was grown on a silicon substrate as in Example 1. In Example 2, zinc oxide nanoparticles were deposited on the silica nanostructures using ALD. The precursor material used was diethyl zinc, which was introduced into a deposition chamber at a chamber pressure of about 1 Ton with the substrate at a temperature of about 300° C. Thereafter, the chamber was pumped out and purged with dry nitrogen. Water vapor was introduced into the chamber as an oxygen source at a chamber pressure of about 1 Ton with the substrate temperature still at about 300° C. Each cycle of zinc precursor and the oxygen source produce a single layer of zinc oxide. In Example 2, the deposition process was repeated for 200 cycles to produce a continuous layer of zinc oxide nanoparticles, where the average particle size was about 100 nm by about 10 nm.

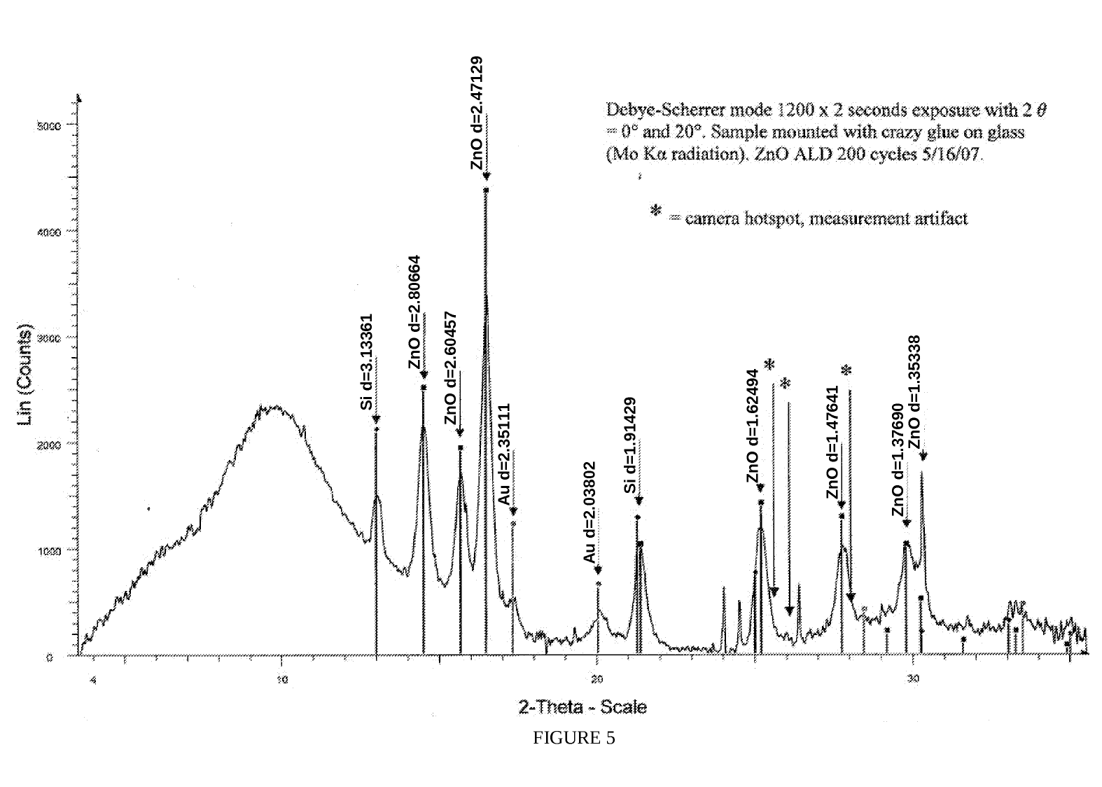

The zinc oxide nanoparticles deposited on the nanostructures are crystalline in Example 2, as determined by the observation of faceting in the SEM image (see FIG. 4), and directly by X-ray diffraction (XRD), as shown in FIG. 5. The XRD spectrum in FIG. 5 shows peaks for Au (corresponding to the catalyst particles on the ends of the nanosprings), Si (from the silicon substrate), and ZnO from the nanoparticles coated on the nanosprings. Because the zinc oxide nanoparticles form a contiguous uniform coating that follows the contours of the nanostructures, a very high conductive surface area electrode may be formed by metallizing silica nanostructures with zinc oxide as described in Example 2, and using a conductive substrate (e.g., aluminum) instead of a silicon substrate on which to grow the silica nanostructures. Metallized nanostructures similar to those illustrated in Examples 1 and 2 have been grown on aluminum substrates.

II. Energy storage devices

The high surface area electrodes described here may be used in any device that utilizes or requires high surface area electrodes. In particular, these electrodes may be used in energy storage devices such as capacitors and ultracapacitors.

The energy storage devices described here comprise first and second electrodes, where at least one of the first and second electrodes comprises a high surface area conductive electrode such as those described above. That is, the energy storage devices disclosed here comprise at least one electrode that comprises a conductive substrate and a mesh of nanostructures coated with conductive or semiconducting nanoparticles, the mesh being disposed on at least a portion of the conductive substrate. In some variations, the mesh is grown directly onto the conductive substrate.

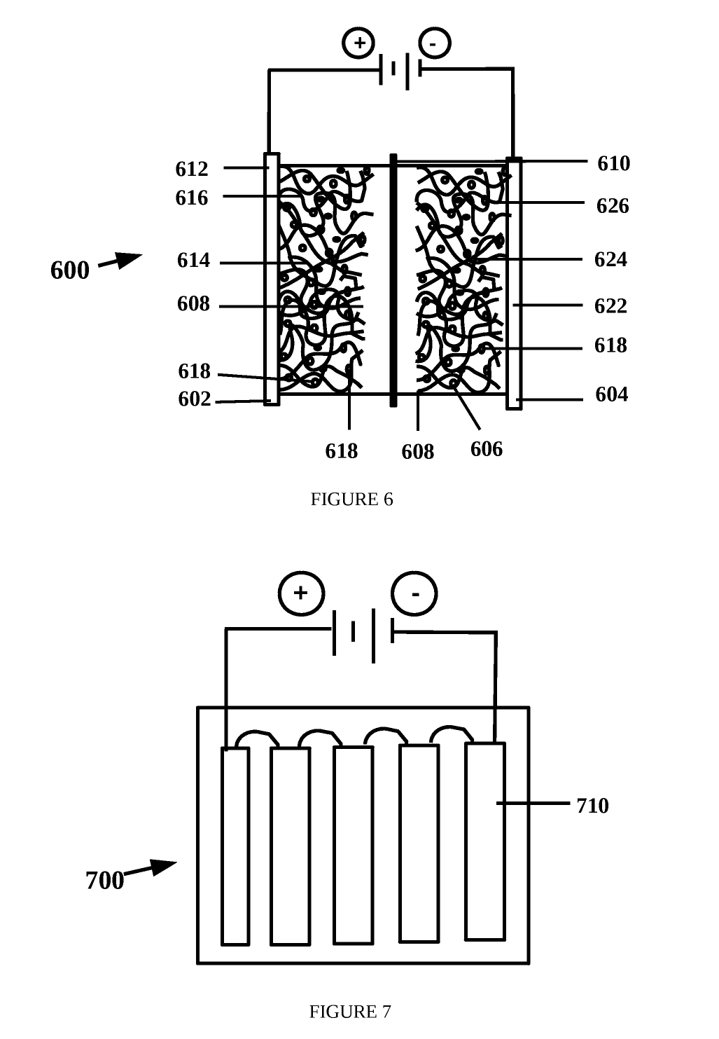

FIG. 6 illustrates a schematic diagram of a variation of an energy storage device. In this variation, the energy storage device is an ultracapacitor. Here, device 600 comprises a first electrode 602 and a second electrode 604 having the opposite polarity. An electrolyte 606 is disposed in a volume 608 between the first electrode 602 and the second electrode 604. A separator (insulating) layer 610 is disposed in the volume 608 between the first and second electrodes to partition the volume. The insulating layer 610 is permeable to ions of the electrolyte. As a potential is applied between the first and second electrodes, energy is stored as charge that builds up at each of the oppositely charged electrodes.

As described above, at least one of the two electrodes of the energy storage device comprises a high surface area conductive electrode that comprises a conductive substrate and a three-dimensional mesh of nanostructures metallized or coated with conductive or semiconducting nanoparticles, the mesh being disposed on at least a portion of the conductive substrate. In some variations of the energy devices, each of the first and second electrodes comprises a conductive substrate and a three-dimensional mesh of nanostructures metallized or coated with conductive or semiconducting nanoparticles, the mesh being disposed on at least a portion of the conductive substrate. For example, the electrode 602 of the energy storage device 600 illustrated in FIG. 6 comprises a conductive substrate 612, and a mesh 614 of nanostructures 616 that have been metallized or coated with conductive or semiconducting nanoparticles (not shown). Similarly, the electrode 604 comprises a conductive substrate 622, and a mesh 624 of nanostructures 626 that have been metallized or coated with conductive or semiconducting nanoparticles (not shown). As illustrated, the mesh of nanostructures is porous to the ions 618 of the electrolyte so that the high conductive surface area provided by the metallized nanostructures is accessible to the energy storage device for storing charge.

For the energy storage devices described here, any of the high surface area conductive electrodes described here may be used, e.g., silica nanostructures metallized or coated with gold, zinc oxide, indium tin oxide, or carbon nanoparticles. Energy storage devices may be symmetrical or asymmetrical with respect to their electrodes. For example, in some variations, one electrode may comprise a high surface area conductive electrode as disclosed herein, and the other electrode may comprise another type of electrode known in the art, e.g., an activated carbon electrode as used in conventional ultracapacitors. In other variations of devices, each electrode may comprise a high surface area conductive electrode as described here. In these variations, the nanostructures and/or nanoparticles coating the nanostructures may be the same or different for each electrode.

Referring now to FIG. 7, a series of ultracapacitor cells as shown in FIG. 6 may be used to provide an energy storage device having an even higher energy storage capacity. In the particular variation illustrated in FIG. 7, energy storage device 700 comprises 5 ultracapacitor cells 710 connected in series. For the single cell ultracapacitor shown in FIG. 6 or the multi-cell ultracapacitor shown in FIG. 7, any suitable device geometry or package may be used, e.g., those device geometries and packing used in conventional ultracapacitors. For example, referring back to FIG. 6, the opposite polarity electrodes 602 and 604 may be arranged as separated and opposed plates, the volume between the plates filled with electrolyte, and the device sealed, so that the ultracapacitor has a parallel-plate type of arrangement, e.g., in a coin-like form. In other variations, the electrodes 602 and 604 may be each formed on a flexible conductive substrate, e.g., a metal foil or a metal-coated polymeric substrate, electrolyte inserted between the electrodes, and the ultracapitor formed as a long strip-like sandwich which is then rolled up, with an insulator (such as insulating paper) placed between the windings. The rolled-up electrode-electrolyte-electrode structure can then be sealed in a can. In still other variations, energy storage devices may comprise an interdigitized electrode arrangement.

For energy storage devices including one or more high surface area conductive electrodes as described here, the density and depth of the nanostructures disposed on at least a portion of the conductive substrate, and the metallization material and thickness may be varied depending on the application, e.g., the desired device dimensions, voltage rating, energy rating, power rating, charge/discharge rating, or a combination thereof. Mesh depths ranging from about 1 μm to about 100 μm may be used. The conductive or semiconducting nanoparticles may be coated on the nanostructures forming the mesh to result in an electrode having an effective conductive surface area of at least about 1,000 cm², at least about 2,000 cm², at least about 3,000 cm², at least about 5,000 cm², at least about 8,000 cm², at least about 10,000 cm², at least about 12,000 cm², at least about 15,000 cm², at least about 18,000 cm², at least about 20,000 cm², or even higher, e.g., at least about 22,000 cm² in a 1 cm² area of the substrate.

In general, to make the high surface area electrodes as disclosed herein accessible to ions in an energy storage device such as an ultracapacitor, the typical feature or crevice size should be sufficient to accommodate an ion of the electrolyte, e.g., tens of angstroms, yet the feature or crevice size should not be so large as to unnecessarily decrease the accessible surface area. A “feature or crevice” of the mesh is meant to encompass any topological feature of the mesh, e.g., intra-nanostructure spaces such as spaces inside tubular or hollow regions, or between coils of a helical structure, and inter-nanostructure spaces. By doing so, the storage capacity of an ultracapacitor device incorporating the high surface area electrodes disclosed here may be increased over a conventional ultracapacitor utilizing activated carbon-coated metal electrodes by a factor of at least about 2, or at least about 3, or at least about 4, or at least about 5 for the same capacitor footprint.

In the energy storage devices, the nanostructures making up the mesh may have any suitable structure, e.g., nanosprings, nanowires, nanotubes, single strand nanostructures, multistrand nanostructures, or any combination thereof. The nanostructures may be formed from any suitable material. For example, nanostructures on at least one of the first and second electrodes may comprise SiO₂, GaN, or SiC. An areal density of the nanostructures on the substrate may be about 5×10⁷/cm² to about 1×10¹¹/cm².

For the energy storage devices, the conductive or semiconducting nanoparticles used to metallize the mesh of nanostructures may comprise a metal, a metal alloy, a metal oxide, carbon, or combinations thereof. In some variations of the devices, the nanoparticles may comprise gold, nickel, copper, aluminum, silver, platinum, palladium, zinc oxide, indium tin oxide, or combinations thereof. In some variations of devices, the nanoparticles may have a dimension of about 100 nm or less, or about 50 nm or less, or about 40 nm or less, or about 30 nm or less, or about 20 nm or less, or about 10 nm or less, or about 5 nm or less, or about 4 nm, or about 3 nm, or about 2 nm.

The electrolyte used in the energy storage devices described here (e.g., electrolyte 606 in device 600 in FIG. 6) may be any suitable electrolyte known in the art or later developed. The electrolyte may be selected based on the voltage rating of the device, the composition of the conductive surface of the electrodes, the mobility of the ions, cost or availability, ease of use in manufacturing, flammability, or any combination of factors. Non-limiting examples of electrolytes that may be used include carbonates, such as propylene carbonate, ethylene carbonate, butylene carbonate, dimethyl carbonate, diethyl carbonate, dipropyl carbonate, methyl ethyl carbonate, methyl butyl carbonate, methyl propyl carbonate, ethyl propyl carbonate, butyl propyl carbonate, 1,2-butylene carbonate, 2,3-butylene carbonate, 1,2-pentene carbonate, 2,3-pentene carbonate. Other compounds that may be used as electrolytes in the ultracapacitors described herein include nitriles, e.g., acetonitrile, acrylonitrile, and propionitrile, sulfoxides, e.g., dimethyl sulfoxide diethyl sulfoxide, ethyl methyl sulfoxide, and benzyl methyl sulfoxide, amides, e.g., formamide and methyl formamide, pyrollidones, e.g., N-methylpyrollidone, esters, e.g., p-butyrolactone, beta-valerolactone, γ-butyrolactone, 2-methyl-γ-butyrolactone, acetyl-gamma-butyrolactone, and γ-valerolactone, phosphate tri-esters, nitromethane, and ethers, e.g., 1,2-dimethoxy ethane, 1,2-ethoxyethane, diethoxyethane, methoxyethoxyethane, dibutoxyethane, dimethoxypropane, diethoxypropane, methoxyethoxypropane, tetrahydrofuran, 2-methyl-tetrahydrofuran, alkyltetrahydrofurans, dialkyltetrahydrofurans, alkoxyltetrahydrofurans, dialkoxytetrahydrofurans, 1,2-dioxolane, 1,3-dioxolane, 1,4-dioxolane, 2-methyldioxolane, 4-methyldioxolane, alkyl-1,3-dioxolanes, sulfolane, 3-methylsulfolane, diethyl ether, diethylene glycol dialkyl ethers, triethylene glycol diethyl ether, ethylene glycol dialkyl ethers, triethylene glycol dialkyl ethers, tetraethylene glycol dialkyl ethers, alkyl propionates such as methyl propionate and ethyl propionate, dialkyl malonates, alkyl acetates, methyl formate, methyl acetate, and maleic anhydride.

An ion-permeable insulating separator used in the ultracapacitors described herein (e.g., separator 610 in device 600 in FIG. 6) may be any suitable separator known in the art or later developed. For example, a thin paper film, thin polymeric film or other membrane, such as those available from Celgard, LLC (Charlotte, N.C.) may be used. The dimensions and permeability of the separator may be selected based on a variety of factors, such as voltage rating, electrolyte volume, and electrolyte type.

The ultracapacitors described herein in general are expected to have a charging time of a few seconds or less, e.g., less than about 5 seconds, less than about 1 second, less than about 0.1 second, or less than about 0.05 seconds, and be able to withstand hundreds of thousands of charge/discharge cycles, e.g., about 3×10⁵, about 5×10⁵, about 1×10⁶, or several or many millions of charge/discharge cycles. In addition, some variations of the ultracapacitors are expected to have energy densities of at least about 2 to about 5 times greater than that of conventional ultracapacitors, e.g., at least about 2 W-h/kg, at least about 5 W-h/kg, at least about 8 W-h/kg, at least about 10 W-h/kg, at least about 20 W-h/kg, at least about 30 W-h/kg, or at least about 40 W-h/kg. Some variations of the ultracapacitors are expected to have power densities of at least about 1 kW/kg, or at least about 2 kW/kg, or at least about 5 kW/kg. For at least these reasons, the ultracapacitors are expected to have applications in both peak-assist and power-assist applications. The energy storage devices may be used in any suitable application now known or later developed, e.g., in a vehicle or automobile, such as a hybrid electric vehicle, in an electronic system, or in a computer system.

### III. Systems

Systems are also provided here. In general, the systems comprise an energy source and an ultracapacitor. The ultracapacitor in the systems comprises first and second electrodes. At least one of the electrodes in the ultracapacitor comprises a high surface area electrode as described herein, i.e., a conductive substrate comprising a mesh of nanostructures metallized with conductive or semiconducting nanoparticles, the mesh being disposed on at least a portion of the conductive substrate. In the ultracapacitor, an electrolyte is disposed in a volume between the first and second electrodes. A separator (insulating) layer that is permeable to ions is disposed in the volume between the first and second electrodes to partition the volume. Any electrolyte and separator layer disclosed herein, or known in the art may be used in the ultracapacitor in the systems.

In the systems, the ultracapacitor is configured to provide back-up energy for the energy source, augment the energy delivered by the energy source, and/or store energy regenerated by the system. The energy source in some variations of the systems may comprise a battery. In other variations of the systems, the energy source may comprise a fuel cell. The systems may be configured for use in a vehicle or automobile, e.g., in a hybrid electric vehicle. For example, the ultracapacitor may provide energy assist during vehicle start up, e.g., cold start up. In a hybrid vehicle, the ultracapacitor may store regenerated energy, e.g., energy regenerated by the braking system.

This disclosure is illustrative and not limiting. Further modifications will be apparent to one skilled in the art in light of this disclosure and such modifications are intended to fall within the scope of the appended claims. Each publication and patent application cited in the specification is incorporated herein by reference in its entirety as if each individual publication or patent application were specifically and individually put forth herein.

What is claimed is:

1. An electrode for use in an energy storage device, the electrode comprising:
a conductive substrate; and
a mesh of nanostructures disposed on the conductive substrate, wherein at least a portion of the nanostructures are coated with conductive or semiconducting nanoparticles to form a high surface area electrode.

2. The electrode of claim 1, wherein the nanostructures are coated with conductive or semiconducting nanoparticles at a coverage sufficient to provide a conductive surface area of at least about 10,000 cm² in a 1 cm² boundary.

3. The electrode of claim 1, wherein the nanostructures are coated with conductive or semiconducting nanoparticles at a coverage sufficient to provide a conductive surface area of at least about 20,000 cm² in a 1 cm² boundary.

4. The electrode of claim 1, wherein the conductive substrate comprises aluminum.

5. The electrode of claim 1, wherein the conductive substrate comprises a polymer.

6. The electrode of claim 1, wherein the conductive or semiconducting nanoparticles comprise a material selected from the group consisting of metals, metal alloys, metal oxides, carbon, and combinations thereof.

7. The electrode of claim 6, wherein the conductive or semiconducting nanoparticles comprise gold, nickel, copper, aluminum, silver, platinum, palladium, or their alloys.

8. The electrode of claim 6, wherein the conductive or semiconducting nanoparticles comprise zinc oxide.

9. The electrode of claim 6, wherein the conductive or semiconducting nanoparticles comprise indium tin oxide.

10. The electrode of claim 1, wherein the mesh has a depth of about 1 micron to about 100 microns.

11. The electrode of claim 1, wherein at least a portion of the nanostructures comprise helical regions.

12. The electrode of claim 1, comprising an areal density of nanostructures from about 5×10⁷/cm² to about 1×10¹¹/cm².

13. The electrode of claim 1, wherein the nanostructures comprise SiO₂, GaN, or SiC.

14. The electrode of claim 1, wherein the conductive or semiconducting nanoparticles have a dimension of about 50 nm or less.

15. The electrode of claim 1, configured for use in a capacitor.

16. The electrode of claim 1, configured for use in an ultracapacitor.

17. A method for making a high surface area electrode, the method comprising:
providing a conductive substrate comprising a mesh of nanostructures secured thereto; and
coating the nanostructures with conductive or semiconducting nanoparticles at a coverage sufficient to provide a high surface area conductive electrode.

18. The method of claim 17, wherein coating the nanostructures comprises depositing the conductive or semiconducting nanoparticles on the nanostructures using atomic layer deposition.

19. The method of claim 17, wherein coating the nanostructures comprises depositing the conductive or semiconducting nanoparticles on the nanostructures using chemical vapor deposition or plasma enhanced chemical vapor depostion.

20. The method of claim 17, comprising growing the mesh of nanostructures on the conductive substrate, wherein the nanostructures comprise SiO₂, GaN or SiC.

21. The method of claim 17, comprising growing the mesh of nanostructures on the conductive substrate, wherein at least a portion of the mesh comprises helical nanostructures.

22. The method of claim 17, comprising growing the mesh of nanostructures on the conductive substrate at a temperature between about 350° C. and about 1100° C.

23. The method of claim 17, comprising making an electrode having a conductive electrode surface area of at least about 10,000 cm² in a 1 cm² boundary.

24. The method of claim 17, comprising coating the mesh of nanostructures with conductive or semiconducting nanoparticles having a dimension of about 50 nm or less.

25. The method of claim 17, comprising coating the mesh of nanostructures with conductive or semiconducting nanoparticles comprising a material selected from the group consisting of metals, metal alloys, metal oxides, and carbon.

26. The method of claim 25, wherein the nanoparticles comprise gold, nickel, copper, aluminum, silver, platinum, palladium, or their alloys.

27. The method of claim 25, wherein the nanoparticles comprise zinc oxide.

28. The method of claim 25, wherein the nanoparticles comprise indium tin oxide.

29. The method of claim 17, comprising growing the mesh of nanostructures on a conductive substrate that comprises aluminum.

30. The method of claim 17, comprising growing the mesh of nanostructures on a conductive substrate that comprises a polymer.

31. The method of claim 17, comprising growing a mesh of nanostructures on a multilayer conductive substrate.

32. An energy storage device comprising:
first and second electrodes, at least one of the electrodes comprising a conductive substrate and a mesh of nanostructures coated with conductive or semiconducting nanoparticles, the mesh disposed on at least a portion of the conductive substrate;
an electrolyte disposed in a volume between the first and second electrodes; and
an insulating layer disposed in the volume between the first and second electrodes to partition the volume, wherein the insulating layer is permeable to ions of the electrolyte.

33. The energy storage device of claim 32, wherein:
the first electrode comprises a first conductive substrate and a first mesh of nanostructures coated with conductive or semiconducting nanoparticles, the first mesh disposed on at least a portion of the first conductive substrate; and
the second electrode comprises a second conductive substrate and a second mesh of nanostructures coated with conductive or semiconducting nanoparticles, the second mesh disposed on at least a portion of the second conductive substrate.

34. The energy storage device of claim 33, wherein at least one of the first and second meshes has a depth of about 1 micron to about 100 microns.

35. The energy storage device of claim 32, wherein at least a portion of the nanostructures are helical.

36. The energy storage device of claim 33, wherein an areal density of nanostructures on at least one of the first and second electrodes is between about 5×10⁷/cm² and about 1×10¹¹/cm².

37. The energy storage device of claim 33, wherein the nanostructures of at least one of the first and second meshes comprises SiO₂, GaN, or SiC.

38. The energy storage device of claim 33, wherein at least one of the first and second electrodes has an effective conductive surface area of at least about 10,000 cm² in a 1 cm² boundary.

39. The energy storage device of claim 33, wherein the nanostructures of at least one of the first and second meshes is coated with conductive or semiconducting nanoparticles comprising a material selected from the group consisting of a metal, a metal alloy, a metal oxide, carbon, and combinations thereof.

40. The energy storage device of claim 39, wherein the nanoparticles on the nanostructures of at least one of the first and second meshes comprise gold, nickel, copper, aluminum, silver, platinum, palladium, or their alloys.

41. The energy storage device of claim 39, wherein the nanoparticles on the nanostructures of at least one of the first and second meshes comprise zinc oxide.

42. The energy storage device of claim 32, wherein the nanoparticles have a dimension of about 50 nm or less.

43. The energy storage device of claim 32, configured for use in an automobile.

44. A system comprising:
an energy source; and
an ultracapacitor comprising:
first and second electrodes, at least one of the electrodes comprising a conductive substrate and a mesh of nanostructures coated with conductive or semiconducting nanoparticles, the mesh disposed on at least a portion of the conductive substrate;
an electrolyte disposed in a volume between the first and second electrodes; and
an insulating layer that is permeable to ions of the electrolyte, the insulating layer disposed in the volume between the first and second electrodes to partition the volume,
wherein the ultracapacitor is configured to provide back up energy for the energy source, augment the energy delivered by the energy source, and/or store energy regenerated by the system.

45. The system of claim 44, wherein the energy source comprises a battery.

46. The system of claim 44, wherein the energy source comprises a fuel cell.

47. The system of claim 44, configured for use in an automobile.
